(19) United States
(12) Patent Application Publication
(10) Pub. No.: US 2006/0144616 A1
(43) Pub. Date: Jul. 6, 2006

(54) Printed circuit board with improved ground plane

(75) Inventors: Yu-Hsu Lin, Fullerton, CA (US); Shang-Tsang Yeh, Tu-Cheng (TW); Wei Li, Shenzhen (CN)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry CO., LTD., Tu-Cheng City (TW)

(21) Appl. No.: 11/316,300

(22) Filed: Dec. 21, 2005

(30) Foreign Application Priority Data
Dec. 30, 2004 (CN) 200420103609.3

(51) Int. Cl. H05K 7/06

(52) U.S. Cl. 174/250; 174/255

(57) ABSTRACT

A ground plane of a printed circuit board (PCB) includes a number of tiles, wherein the tiles are so regularly arranged that no matter in which way a straight signal line segment is arranged on a signal plane of the PCB, a return current path on the tiles corresponding to the signal line segment is not in a straight line, thereby reducing the difference in impedance of return current paths.

### BACKGROUND

1. Field of the Invention

The present invention relates to a printed circuit board (PCB) with an improved ground plane.

2. General Background

In designing a contemporary PCB, controlling trace impedance is very important. The impedance relates to a number of parameters, such as the width and the distance of signal traces, and the thickness of metal layers of the PCB, etc. Typically, the parameters are changed in order to adjust the trace impedance in a preferred arrangement. However, it is not enough to just adjust the above parameters when designing a thin PCB.

Another factor influencing trace impedance is the ground plane. Typically, a grid (square mesh formed by ground traces) ground plane is used. Depending on where a signal trace is arranged on a signal plane, a return current will pass through different ways on the grid ground plane and result in different impedances. Referring to FIG. 5A, when a signal trace L′ of a signal plane is arranged to coincide with a central parallel line of two neighboring lines of the ground plane, then most of the return current follows a path Pmax′ at the ground plane and also a path (not shown) that is a mirror-image of the path Pmax′. The path Pmax′ is the longest path possible among all situations. If the same signal trace L′ of the signal plane is coincident with a line of the ground plane, then most of the return current follows a path Pmin′ at the ground plane which is coincident with the signal trace L′. The path Pmin′ is the shortest path possible among all situations.

Referring to FIGS. 5B and 5C, test results show that an average impedance caused by a return current following a maximum distance path Pmax′ of FIG. 5A is 89.13 ohms, and an average impedance caused by a return current following a minimum distance path Pmin′ of FIG. 5A is 33 ohms. The difference of the impedances is 89.13−33=56.13 ohms.

When the signal trace L′ is arranged in the above-mentioned two ways respectively, the difference in length of the two paths Pmax′ and Pmin′ is very great, therefore the difference of the characteristic impedances of the signal trace L′ is very great as well. That means the impedance varies over a large range according to the location and angle in the placement of the signal trace on the ground plane. However, in designing the PCB, to achieve a better signal quality, the characteristic impedances (transient impedances) must be kept close to a constant value.

What is needed, therefore, is a PCB with an improved ground plane.

### SUMMARY

An exemplary ground plane of a printed circuit board (PCB) includes a number of tiles, wherein the tiles are so regularly arranged that no matter which way a straight signal line segment is arranged on a signal plane of the PCB, a return current path on the tiles corresponding to the signal line segment is not in a straight line, thereby reducing the difference in impedance of the paths the return current may follow.

Other advantages and novel features will become more apparent from the following detailed description when taken in conjunction with the accompanying drawings, in which:

### BRIEF DESCRIPTION OF THE DRAWINGS

FIG. 1A is a top plan view of a ground plane of a PCB in accordance with a first embodiment of the present invention, with a straight signal line segment cast thereon in two positions;

FIG. 1B is a graph of the impedance of a return current following a maximum distance path Pmax1 of FIG. 1A over time;

FIG. 1C is a graph of the impedance of a return current following a minimum distance path Pmin1 of FIG. 1A over time;

FIG. 2A is a top plan view of a ground plane of a PCB in accordance with a second embodiment of the present invention, with a straight signal line segment cast thereon in two positions;

FIG. 2B is a graph of the impedance of a return current following a maximum distance path Pmax2 of FIG. 2A over time;

FIG. 2C is a graph of the impedance of a return current following a minimum distance path Pmin2 of FIG. 2A over time;

FIG. 3A is a top plan view of a ground plane of a PCB in accordance with a third embodiment of the present invention, with a straight signal line segment cast thereon in two positions;

FIG. 3B is a graph of the impedance of a return current following a maximum distance path Pmax3 of FIG. 3A over time;

FIG. 3C is a graph of the impedance of a return current following a minimum distance path Pmin3 of FIG. 3A over time;

FIG. 4 is a top plan view of a ground plane of a PCB in accordance with a fourth embodiment of the present invention, with a straight signal line segment cast thereon in two positions;

FIG. 5A is a top plan view of a conventional ground plane of a PCB, with a straight signal line segment cast thereon in two positions;

FIG. 5B is a graph of the impedance of a return current following a maximum distance path Pmax′ of FIG. 5A over time; and

FIG. 5C is a graph of the impedance of a return current following a minimum distance path Pmin′ of FIG. 5A over time.

### DETAILED DESCRIPTION OF THE EMBODIMENTS

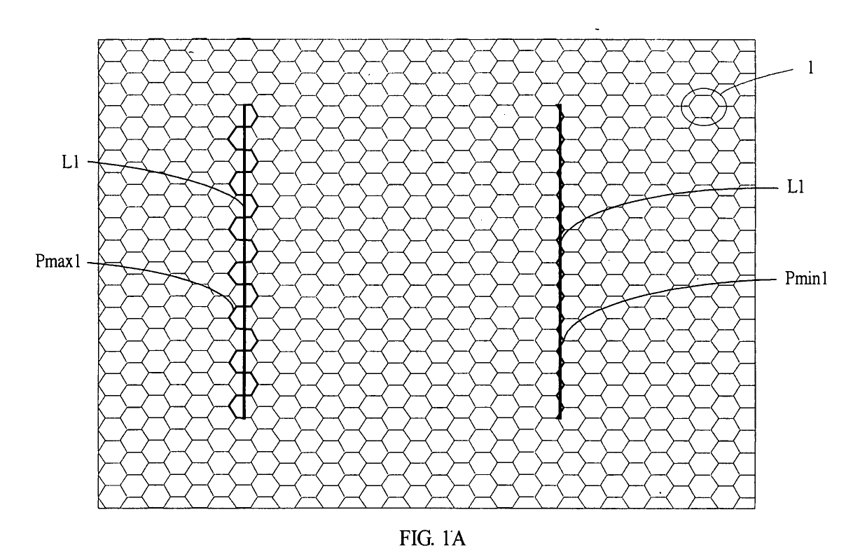

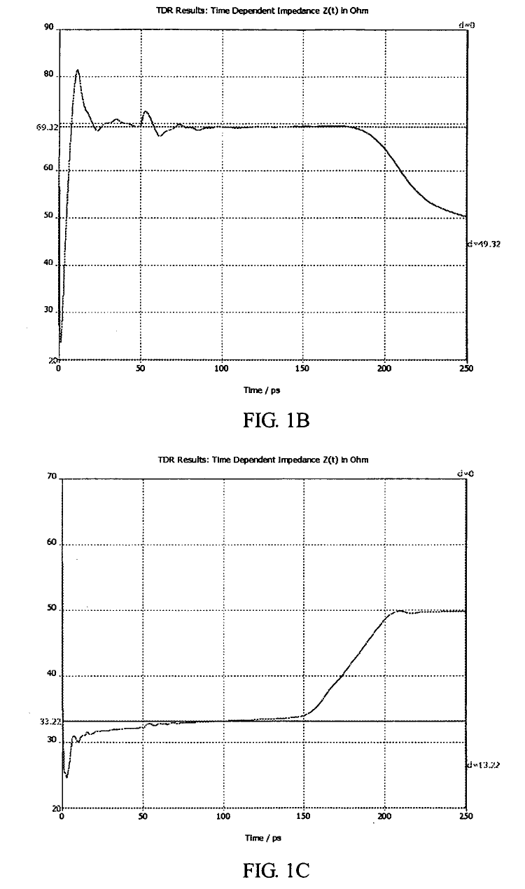

Referring to FIG. 1A, a ground plane or reference plane of a PCB in accordance with a first embodiment of the present invention is shown. The ground plane of the first embodiment includes a plurality of same-sized compactly arrayed regular hexagon-shaped tiles 1. Each tile 1 is surrounded by ground traces.

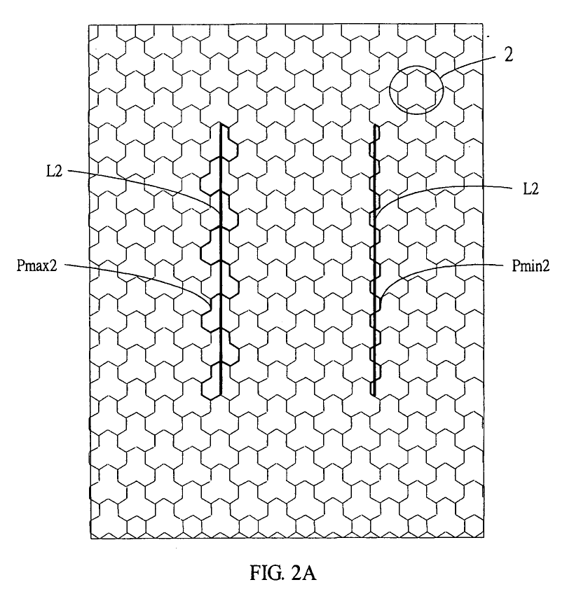

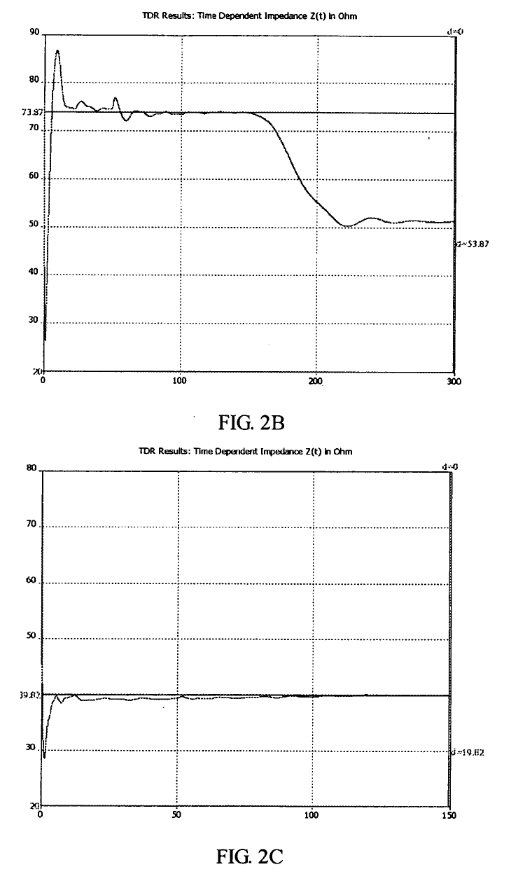

Referring to FIG. 2A, a ground plane of a PCB in accordance with a second embodiment of the present invention is shown. The ground plane of the second embodiment includes a plurality of same-sized Y-shaped tiles 2. Each tile 2 is a polygon with twelve sides resembling the shape of three regular hexagons 1 combined. Each side of the tile 2 is a ground trace.

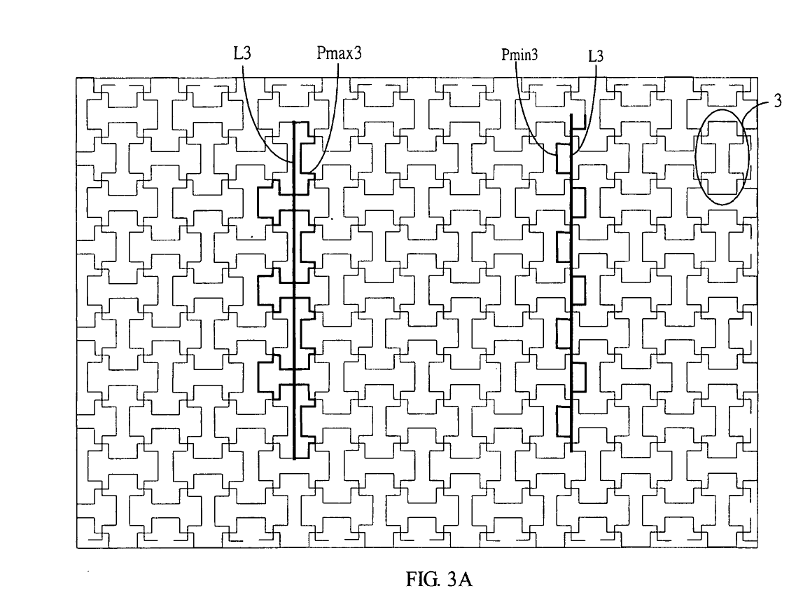

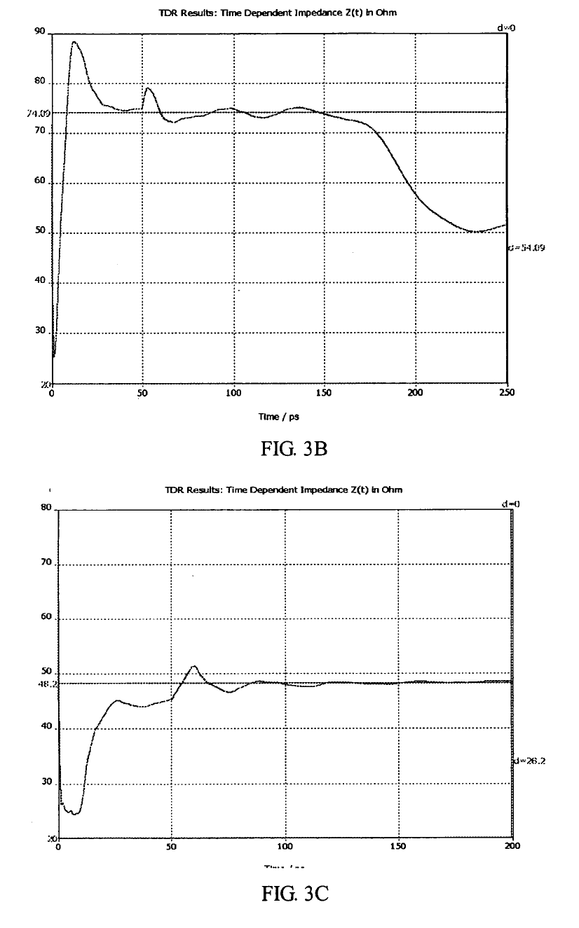

Referring to FIG. 3A, a ground plane of a PCB in accordance with a third embodiment of the present invention is shown. The ground plane of the third embodiment includes a plurality of same-sized tiles 3. Each tile 3 includes an “H” configuration and two protrusions formed at two opposing long sides of the “H” surrounded by ground traces. Each tile 3 is rotated 90 degrees in orientation to its neighboring tiles. Each tile 3 is a polygon with twenty sides and is symmetrical about both its horizontal axis and its vertical axis.

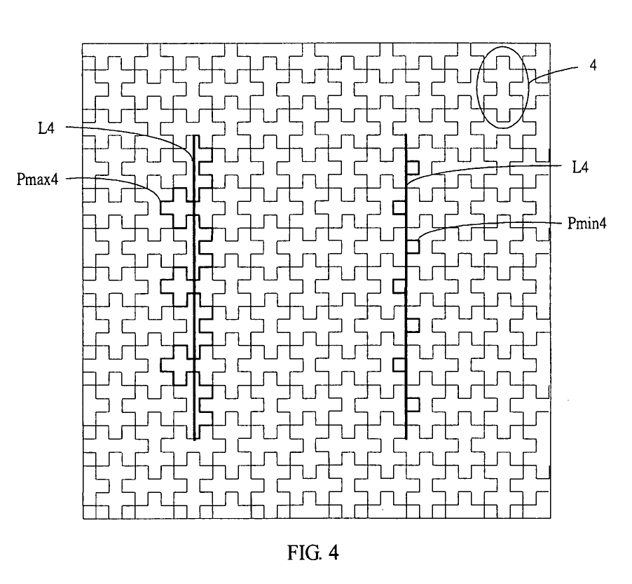

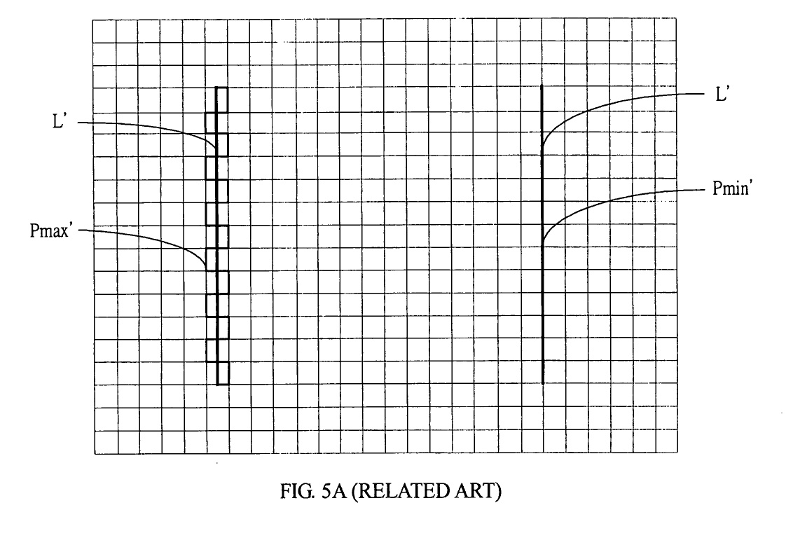

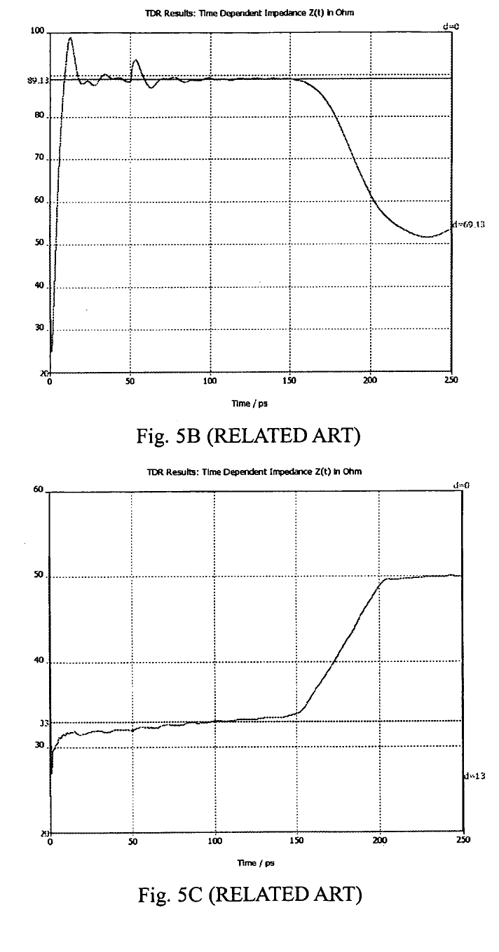

Referring to FIG. 4, a ground plane of a PCB in accordance with a fourth embodiment of the present invention is shown. The ground plane of the fourth embodiment includes a plurality of same-sized double-cross shaped tiles 4. Each tile 4 is rotated 90 degrees in orientation to its neighboring tiles. Each tile 4 is a polygon with twenty sides and is symmetrical about both its horizontal axis and its vertical axis. Each side of the tile 4 has a ground trace thereat.

The influence of the ground planes of the four embodiments to the characteristic impedance of the signal trace arranged in different ways is described as follows. Simply stated, a straight-line signal trace is intercepted, and a signal comes from a signal source, crosses the signal trace and the ground plane, and then returns to the signal source. Generally, a length of a line segment of the ground plane, such as a side of one of the regular hexagon-shaped tiles 1, is about 5 mm. The tiles of the ground plane can be so designed as to ensure the length of any of the line segments is shorter than the length of any signal trace to be used. For the purposes of conveniently describing the present embodiments it is assumed that any of the line segments of the ground plane is no greater than 5 mm in length and that all signal traces are greater than 5 mm in length. Only maximum and minimum distance paths followed by a return current through the ground plane are illustrated.

The FIGS. 1A, 2A, 3A, and 4 respectively show signal traces L1, L2, L3, and L4 each depicted in two positions. The left portion of each figure shows the signal trace arranged at a position which a return current follows a longest path. Most of the return current passes through a path Pmax1, Pmax2, Pmax3, or Pmax4, and a path (not shown) that is mirror-imaging the corresponding path Pmax1, Pmax2, Pmax3, or Pmax4 along the signal trace. The right portion of each figure shows the signal trace arranged at a position which a return current follows a shortest path. Most of the return current passes through a path Pmin1, Pmin2, Pmin3, or Pmin4.

Referring to FIGS. 1B and 1C, test results show that an average impedance caused by a return current following a maximum distance path Pmax1 of FIG. 1A is 69.32 ohms, and an average impedance caused by a return current following a minimum distance path Pmin1 of FIG. 1A is 33.22 ohms. The difference of the impedances is 69.32−33.22=36.1 ohms.

Referring to FIGS. 2B and 2C, test results show that an average impedance caused by a return current following a maximum distance path Pmax2 of FIG. 2A is 73.87 ohms, and an average impedance caused by a return current following a minimum distance path Pmin2 of FIG. 2A is 39.82 ohms. The difference of the impedances is 73.87−39.82=34.05 ohms.

Referring to FIGS. 3B and 3C, test results show that an average impedance caused by a return current following a maximum distance path Pmax3 of FIG. 3A is 74.09 ohms, and an average impedance caused by a return current following a minimum distance path Pmin3 of FIG. 3A is 48.2 ohms. The difference of the impedances is 74.09−48.2=25.89 ohms.

Referring to the FIGS. 1A, 2A, 3A, and 4, no matter how the signal trace is placed, the return current cannot pass through a straight path. In a same application circumstance, when the signal trace is arranged in various positions, the difference in the distance of the return current's paths has been reduced compared with that of the related art 5A. Therefore, the ground planes of the preferred embodiments of the present invention are capable of reducing the range of the difference of the characteristic impedances caused by differing placements of the signal trace.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments.

What is claimed is:

1. A ground plane of a printed circuit board (PCB) comprising a plurality of tiles, wherein the tiles are regularly arranged so that a straight signal line segment is capable of being located anywhere on a signal plane of the PCB and at least a two-segment rectilinear path between tiles is followed by a return current.

2. The ground plane as claimed in claim 1, wherein each of the tiles is a regular hexagon-shaped tile.

3. The ground plane as claimed in claim 1, wherein each of the tiles has a “Y” shape, the “Y” shape is a polygon with twelve sides resembling the shape of three regular hexagons combined.

4. The ground plane as claimed in claim 1, wherein each of the tiles comprises an “H” configuration and two protrusions formed at two opposite long sides of the “H”, each of the tiles is rotated 90 degrees in orientation to its neighboring tiles.

5. The ground plane as claimed in claim 4, wherein each of the tiles is a polygon with twenty sides and is symmetrical about both its horizontal axis and its vertical axis.

6. The ground plane as claimed in claim 1, wherein each of the tiles is a double-cross shaped tile, and each of the tiles is rotated 90 degrees in orientation to its neighboring tiles.

7. The ground plane as claimed in claim 6, wherein each of the tiles is a polygon with twenty sides and is symmetrical about both its horizontal axis and its vertical axis.

8. A ground plane of a printed circuit board (PCB) comprising a plurality of tiles, wherein the tiles are so arranged that no matter in which way a straight signal line segment is arranged on a signal plane of the PCB, a return current path on the tiles corresponding to the signal line segment is not in a straight line, thereby reducing the difference in impedance of return current paths.

9. An electronic assembly comprising:
a signal plane of said assembly capable of defining a plurality of signal traces with a predetermined length respectively; and
a reference plane of said assembly disposed beside said signal plane in a substantially parallel manner, said reference plane defining a plurality of reference traces therein respectively with a length shorter than said predetermined length of said plurality of signal traces, said reference traces being arranged in said reference plane by a manner that no signal trace out of said plurality of signal traces overlaps two neighboring connected reference traces out of said plurality of reference traces along a normal direction of said reference plane.

10. The electronic assembly as claimed in claim 9, wherein said plurality of reference traces is arranged to form a plurality of regular-hexagon-shaped tiles.

11. The electronic assembly as claimed in claim 9, wherein said plurality of reference traces is arranged to form a plurality of Y-shaped tiles, each of which is formed as a polygon with twelve sides resembling the shape of three regular hexagons combined.

12. The electronic assembly as claimed in claim 9, wherein said plurality of reference traces is arranged to form a plurality of H-shaped tiles, each of which is formed as an “H” configuration with two protrusions formed at two opposite long sides of said “H” configuration and is rotatable by 90 degrees in orientation to fit in with neighboring tiles thereof.

13. The electronic assembly as claimed in claim 9, wherein said plurality of reference traces is arranged to form a plurality of polygon-like tiles, each of which is formed as a polygon with twenty sides and symmetrically about both of a horizontal axis and a vertical axis thereof.

14. The electronic assembly as claimed in claim 9, wherein said plurality of reference traces is arranged to form a plurality of double-cross-shaped tiles, each of which is rotatable by 90 degrees in orientation to fit in with neighboring tiles thereof.
